(19) United States
(12) Patent Application Publication
(10) Pub. No.: US 2013/0341070 A1
(43) Pub. Date: Dec. 26, 2013

(54) TOUCH PANEL

(71) Applicant: SAMSUNG ELECTRO-MECHANICS CO., LTD., Suwon (KR)

(72) Inventors: Hyun Kim, Suwon (KR); Victor Yurlov, Suwon (KR)

(21) Appl. No.: 13/914,851

(22) Filed: Jun. 11, 2013

(30) Foreign Application Priority Data
Jun. 25, 2012 (KR) 10-2012-0068100

(51) Int. Cl. H05K 1/02

(52) U.S. Cl. CPC H05K 1/0213
USPC 174/250

(57) ABSTRACT

Disclosed herein is a touch panel, including: mesh conductor lines, wherein a pitch of the mesh conductor line has a value selected from pₘ=2×p_{d}(fₘ=f_{d}/2, pₘ≦260 μm), wherein pₘ is a pitch of the mesh conductor line, p_{d} is a pixel pitch of a display, fₘ is a frequency 1/pₘ of the mesh conductor line, and f_{d} is a pixel frequency 1/p_{d} of the display.

### CROSS REFERENCE TO RELATED APPLICATION

This application claims the benefit of Korean Patent Application No. 10-2012-0068100, filed on Jun. 25, 2012, entitled “Touch Panel”, which is hereby incorporated by reference in its entirety into this application.

### BACKGROUND OF THE INVENTION

1. Technical Field

The present invention relates to a touch panel.

2. Description of the Related Art

In accordance with the growth of computers using a digital technology, devices assisting computers have also been developed, and personal computers, portable transmitters and other personal information processors execute processing of text and graphic using a variety of input devices such as a keyboard and a mouse.

In accordance with the rapid advancement of an information-oriented society, the use of computers has gradually been widened; however, it is difficult to efficiently operate products using only a keyboard and a mouse currently serving as an input device. Therefore, the necessity for a device that is simple, has minimum malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

This touch panel is mounted on a display surface of an image display device such as an electronic organizer, a flat panel display device including a liquid crystal display (LCD) device, a plasma display panel (PDP), an electroluminescence (El) element, or the like, and a cathode ray tube (CRT) to thereby be used to allow a user to select desired information while viewing the image display device.

Meanwhile, the touch panel is classified into a resistive type touch panel, a capacitive type touch panel, an electromagnetic type touch panel, a surface acoustic wave (SAW) type touch panel, and an infrared type touch panel. These various types of touch panels are adopted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch panel and the capacitive type touch panel have been prominently used in a wide range of fields.

In this touch panel, a conductor line is generally made of an indium tin oxide (ITO). However, the ITO has excellent electrical conductivity but is expensive since indium used as a raw material thereof is a rare earth metal. In addition, the indium is expected to be depleted within the next decade, such that it may not be smoothly supplied.

Due to the above-mentioned reason, as disclosed in the following Patent Document, research into a technology of forming a conductor line using a metal has been actively conducted. When the conductor line is made of the metal, it is advantageous in that the metal has much more excellent electrical conductivity as compared with the ITO and may be smoothly supplied. However, in the case of the prior art, when the conductor line is made of the metal, there is a visibility problem that the conductor line is viewed by user's eyes, a moire problem generated by an interference between a display pattern and the conductor line or the like, such that commercialization is difficult.

### SUMMARY OF THE INVENTION

The present invention has been made in an effort to provide a touch panel capable of shortening a development period and increasing efficiency of the development by significantly decreasing trial and error in design of conductor lines as well as and implementing higher quality using optimal design parameters.

According to a preferred embodiment of the present invention, there is provided a touch panel, including: mesh conductor lines, wherein a pitch of the mesh conductor line has a value selected from pₘ=2×p_{d}(fₘ=f_{d}/2, pₘ≦260 μm), wherein pₘ is a pitch of the mesh conductor line, p_{d} is a pixel pitch of a display, fₘ is a frequency 1/pₘ of the mesh conductor line, and f_{d} is a pixel frequency 1/p_{d} of the display.

The mesh conductor line may have a line width of 1 μm through 5 μm.

The mesh conductor line may have a tilt angle of 30° or 60°.

The touch panel may further include a sensing electrode and a driving electrode configured of the mesh conductor line.

The sensing electrode and the driving electrode may be formed on surfaces different from each other, and the mesh conductor line of the sensing electrode and the mesh conductor line of the driving electrode may be arranged to be misaligned to each other by a half period.

The sensing electrode and the driving electrode may be formed on the same surface as each other.

According to another preferred embodiment of the present invention, there is provided a touch panel, including: a sensing electrode and a driving electrode configured of mesh conductor lines, wherein when a length of one side of a polygon formed by intersecting the mesh conductor lines of the sensing electrode or a polygon formed by intersecting the mesh conductor lines of the driving electrode is defined as a length of a unit electrode pattern, a length of one side of a polygon formed by intersecting the mesh conductor line of the sensing electrode and the mesh conductor line of the driving electrode with each other is defined as a length of a unit mesh conductor line, and a length vertically connecting between the mesh conductor line of the sensing electrode and the mesh conductor line of the driving electrode adjacent to each other is defined as a pitch of the unit mesh conductor line, the length of the unit electrode pattern has a value selected from L=2×Lₘ=2×pₘ/sin(2θₘ), wherein L is the length of the unit electrode pattern, Lₘ is the length of the unit mesh conductor line, pₘ is the pitch of the unit mesh conductor line, and θₘ is a tilt angle of the mesh conductor line.

According to another preferred embodiment of the present invention, there is provided a touch panel, including: mesh conductor lines, wherein a line width of the mesh conductor line and a pitch of the mesh conductor line have values selected from Tₘ=T×(1−W/pₘ)²≧89%, 1 μm≦W≦5 μm, pₘ≦260 μm so that the touch panel satisfies transmissivity of 89% or more, wherein Tₘ is transmissivity of the touch panel, T is transmissivity of the touch panel without the mesh conductor line, W is the line width of the mesh conductor line, and pₘ is the pitch of the mesh conductor line.

The mesh conductor line may have a tilt angle of 30° or 60°.

The touch panel may further include a sensing electrode and a driving electrode configured of the mesh conductor line.

The sensing electrode and the driving electrode may be formed on surfaces different from each other, and the mesh conductor line of the sensing electrode and the mesh conductor line of the driving electrode may be arranged to be misaligned to each other by a half period.

The sensing electrode and the driving electrode may be formed on the same surface as each other.

According to another preferred embodiment of the present invention, there is provided a touch panel, including: mesh conductor lines, wherein when a resistance of one side of a polygon formed by intersecting the mesh conductor lines is defined as a unit resistance of a unit electrode pattern, and a length of one side of a polygon formed by intersecting the mesh conductor lines is defined as a length of a unit electrode pattern, conductivity of a conductor forming the mesh conductor lines, a thickness of the mesh conductor line, and a line width of the mesh conductor line have values selected from Rᵤₘ=L/(σ×A), A=t×W so that the unit electrode pattern has the unit resistance of 50Ω or less, wherein Rᵤₘ is the unit resistance of the unit electrode pattern, L is the length of the unit electrode pattern, σ is the conductivity of the conductor forming the mesh conductor lines, t is the thickness of the mesh conductor line, and W is the line width of the mesh conductor line.

The mesh conductor line may have a tilt angle of 30° or 60°.

The touch panel may further include a sensing electrode and a driving electrode configured of the mesh conductor line.

The sensing electrode and the driving electrode may be formed on surfaces different from each other, and the mesh conductor line of the sensing electrode and the mesh conductor line of the driving electrode may be arranged to be misaligned to each other by a half period.

The sensing electrode and the driving electrode may be formed on the same surface as each other.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a test chart for evaluating contrast sensitivity which is pattern distinction capability of a human eye;

FIG. 2A is a graph showing contrast sensitivity with respect to a spatial frequency of cycles/degree in unit;

FIG. 2B is a graph showing contrast sensitivity with respect to a spatial frequency of linepair/mm in unit;

FIGS. 3A and 3B are views showing pixel arrangement structures of an LCD display having a size of 3.8 inches employed in an actual mobile phone;

FIG. 3C is a view showing mesh conductor lines;

FIG. 4 is a graph showing a moiré phenomenon with respect to the spatial frequency;

FIG. 5 is a graph showing a moiré phenomenon having a high frequency with respect to the spatial frequency;

FIG. 6 is a cross-sectional view of a touch panel employing mesh conductor lines panel according to one preferred embodiment of the present invention;

FIG. 7 is a plan view showing two sensing electrodes and two driving electrodes at a left lower end portion of the touch panel;

FIG. 8 is an enlarged view of enlarging the sensing electrode and the driving electrode shown in FIG. 7;

FIGS. 9 and 10 are graphs showing transmissivity of the touch panel employing the mesh conductor lines;

FIG. 11A is a plan view showing the driving electrode of the touch panel;

FIG. 11B is a plan view showing the sensing electrode of the touch panel;

FIG. 12A is a graph showing change of a terminal resistance of the driving electrode with respect to the pitch of the mesh conductor lines; and

FIG. 12B is a graph showing change of a terminal resistance of the sensing electrode with respect to the pitch of the mesh conductor lines.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the to same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

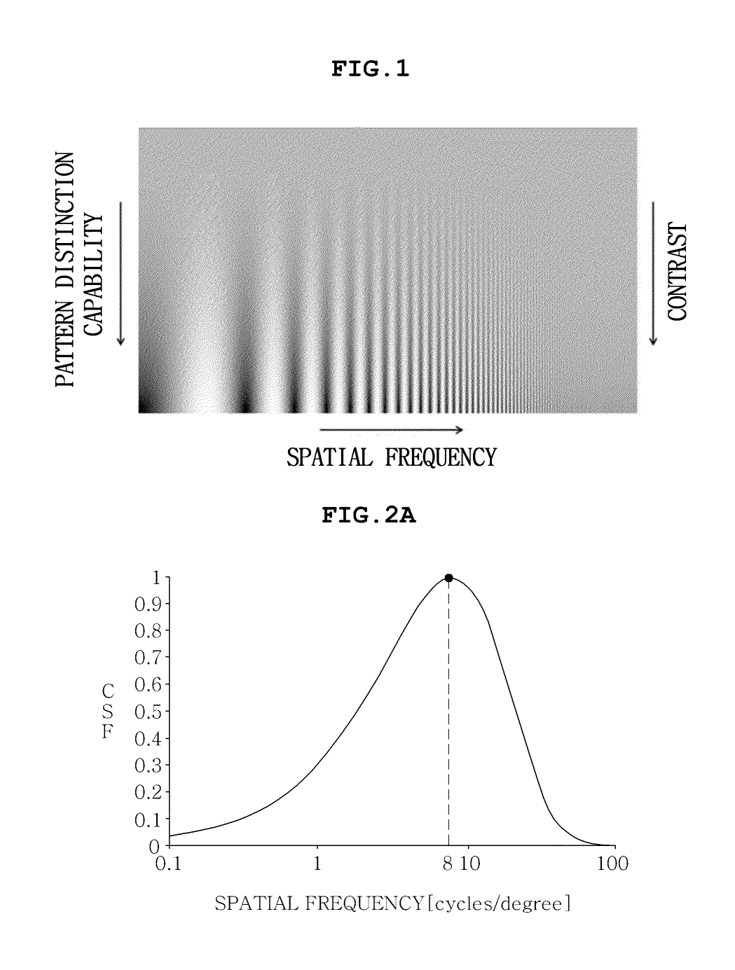

FIG. 1 is a test chart for evaluating contrast sensitivity which is pattern distinction capability of a human eye. As shown in FIG. 1, a spatial frequency of a pattern becomes higher toward a right direction (that is, a pitch of the pattern becomes shorter). In addition, it may be confirmed that contrast becomes higher toward a lower direction and pattern distinction capability also becomes better. The most important point is that patterns having low contrast are also distinguished in the vicinity of an intermediate point of the spatial frequency in FIG. 1. That is, contrast sensitivity relatively becomes higher at the intermediate point of the spatial frequency. The contrast sensitivity at the spatial frequency corresponding thereto is defined as a reciprocal number of the minimum contrast value capable of distinguishing the pattern. It may be confirmed that it is difficult to distinguish even the pattern having a high contrast value at a high spatial frequency. That is, it may be confirmed that the contrast sensitivity becomes lower at this high spatial frequency.

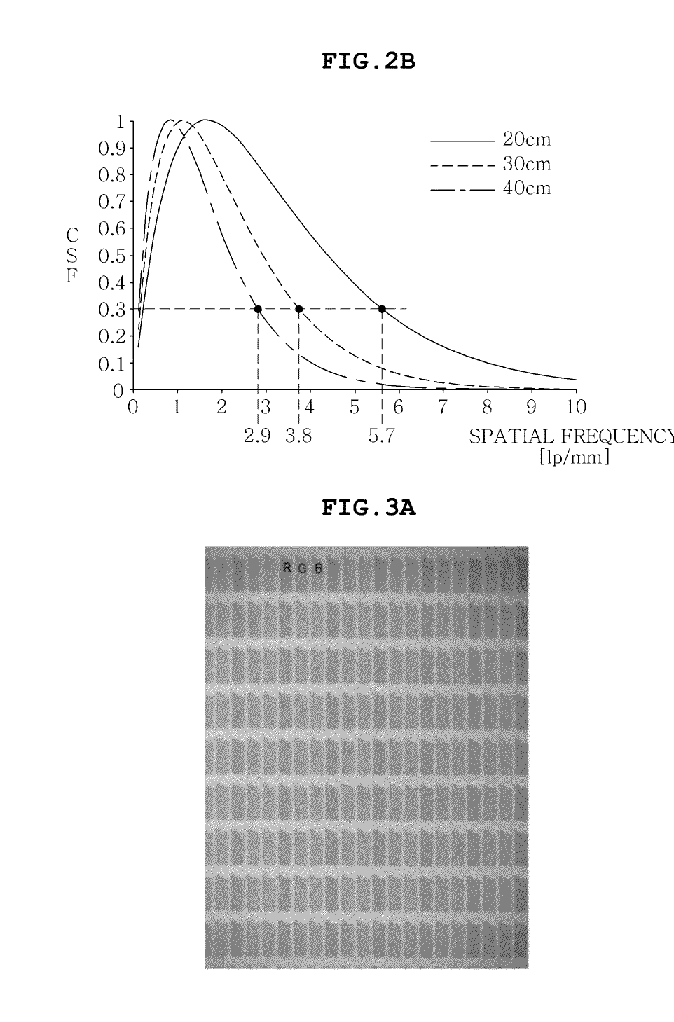

A way in which human eye distinguishes a specific pattern is that optical performance and response characteristics of a crystalline lens of the eye, filter characteristics of an optic nerve, and the like are complexly worked, such that a brain finally recognizes the specific pattern. This recognition capability by human is closely related to contrast of the pattern, photography techniques or display techniques trades has accumulated statistical data through a variety of experiments for several decades as contrast sensitivity function (CSF), and a CSF curve as shown in FIG. 2 has been obtained from this data. As shown in FIGS. 1 and 2, it may be confirmed that capability of allowing the human eye to distinguish the specific pattern is significantly dependent on the spatial frequency of the corresponding pattern. FIG. 2A is a graph showing contrast sensitivity with respect to a spatial frequency of cycles/degree in unit and FIG. 2B is a graph showing contrast sensitivity with respect to a spatial frequency of linepair/mm in unit. Here, FIG. 2A is a result representing as a form of the number of patterns per unit angle regardless of an observation distance from a user and FIG. 2B is a result converting the result of FIG. 1 into a form of the number of patterns per unit length. In this case, a test pattern was assumed to be a sinusoidal pattern at the corresponding frequency as shown in FIG. 1. It may be confirmed from FIG. 2A that the human eye best distinguishes patterns of 8 cycle/degree and it may be confirmed from FIG. 2B that a location of this peak contrast sensitivity is changed depending on the observation distance from the user. That is, once the observation distance becomes closer, the pattern of a relatively high spatial frequency may well be distinguished. From FIG. 2 derived from a statistical research result of psychophysics for several decades, when a CSF value is less than 30%, it may be said that it is difficult to distinguish this pattern with the human eye having normal vision. It may be confirmed from FIG. 2b that the spatial frequency corresponding to the CSF value which is less than 30% is approximately 2.9 lp/mm at the distance of 40 cm, is approximately 3.8 lp/mm at the distance of 30 cm, and is approximately 5.7 lp/mm at the distance of 20 cm. That is, it may be confirmed that as the distance becomes closer, the spatial frequency of the pattern in which it is difficult to distinguish with the eye increasingly becomes higher. Currently, the distance of distinguishing the visibility with the naked eye is approximately 30 cm through 40 cm, and this distance is a value assumed as a distance using a portable device such as a general mobile phone, or the like. Therefore, mesh conductor lines are not to be recognized by the eye of the user at the distance of 30 cm at the time of designing the touch panel. In order for the mesh conductor lines not to be recognized by the eye of the user at the distance of 30 cm, it may be confirmed from FIG. 2B that the mesh conductor lines need to be formed so as to have the spatial frequency of 3.8 lp/mm or more. Here, since 3.8 lp/mm corresponds to the pitch of 263 μm, it may be required that the pitch of the mesh conductor lines is formed to be about 260 μm or less.

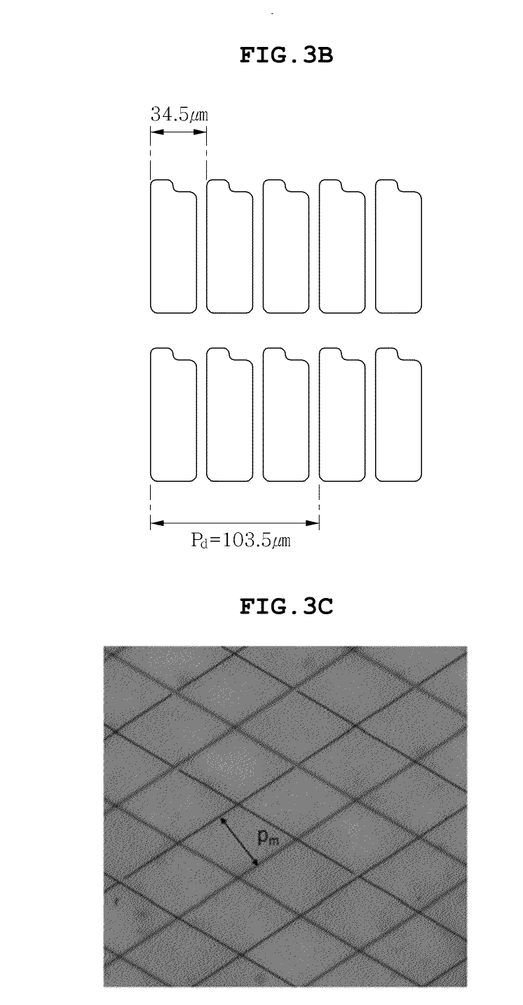

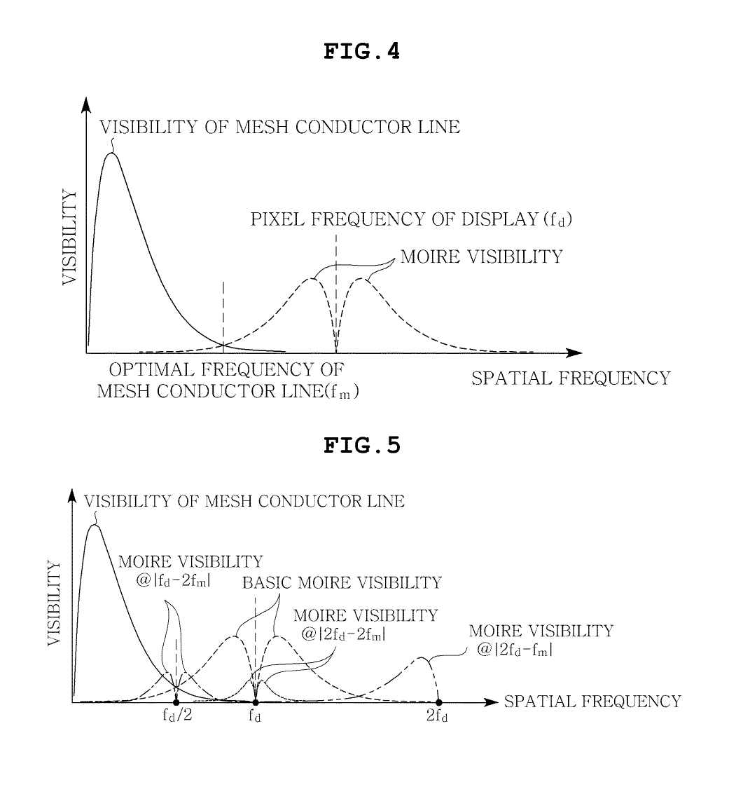

FIGS. 3A and 3B are views showing pixel arrangement structures of an LCD display having a size of 3.8 inches employed in an actual mobile phone. It may be confirmed that the pixel arrangement structure of the LCD display represents a form in which R/G/B pixels are periodically arranged in a horizontal direction. FIG. 3C is a view showing the mesh conductor lines. As shown in FIG. 3B, a pitch of one display pixel is 34.5 μm and a pitch (p_{d}) of R/G/B pixel is 103.5 μm. In addition, as shown in FIG. 3C, the pitch of the mesh conductor line may be defined as pₘ. The pattern generated from the periodic arrangement structure of the display shown in FIGS. 3A and 3B may easily interfere with the pattern generated from the periodic arrangement structure of the mesh conductor lines shown in FIG. 3C. As a result of the interference as mentioned above, the moiré phenomenon occurs and this phenomenon is easily recognized by the eye of the user. Therefore, there is a need to suppress or avoid this moiré phenomenon. FIG. 4 is a graph showing a moiré phenomenon with respect to the spatial frequency. When defining a pixel frequency of the display as f_{d} (1/p_{d}) and a frequency of the mesh conductor line as fₘ (=1/pₘ), it may be confirmed that the visibility of the mesh conductor line visible to the eye of the user becomes lower as the spatial frequency becomes higher (that to is, as the spatial frequency becomes higher, it is difficult to distinguish the mesh conductor line with the eye.). Meanwhile, it may be confirmed that moiré visibility is relatively complicated. The best ideal method is that the frequency (fₘ) of the mesh conductor line is formed to be the same as the pixel frequency f_{d} of the display, but this method is not advantageous in view of an actual manufacture. As shown in FIG. 4, the moiré visibility is sharply increased at left and right of the pixel frequency f_{d}, such that a tolerance of manufacturing the mesh conductor line is decreased. Therefore, it is difficult to actually apply. On the other hand, it may be confirmed that the moiré visibility increasingly becomes lower at a side lower than the pixel frequency f_{d} of the display. In FIG. 4, a point at which the moiré visibility and the visibility of the mesh conductor line intersect with each other may be considered as an optimal frequency fₘ of the mesh conductor line. Although FIG. 4 shows the moiré visibility having a basic frequency, a plurality of moiré visibility having a high frequency in addition to the basic frequency may actually exist. FIG. 5 is a graph showing a moiré phenomenon having a high frequency with respect to the spatial frequency. As shown in FIG. 5, it may be confirmed that the moiré visibility may disappear at a frequency (fₘ=f_{d}/2) of the mesh conductor line that is a half of the basic frequency. In addition, it may be confirmed that the moiré visibility disappear at the high frequency of the mesh conductor line of fₘ=2f_{d}, but it may be confirmed that a frequency tolerance of the mesh conductor line relatively becomes smaller. That is, it may be confirmed that the moiré visibility is sharply increased at left and right of fₘ=2f_{d}. Therefore, it may be said that the moiré visibility optimally becomes lower at a low frequency of fₘ=f_{d}/2.

In the case of the touch panel mounted on the LCD display having the size 3.8 inches of FIG. 3B, the optimal frequency of the mesh conductor line is fₘ=f_{d}/2=(1/103.5 μm)/2=4.8 lp/mm. Here, since 4.8 lp/mm corresponds to the pitch of 207 μm, it may be considered that the moiré visibility optimally becomes lower at the pitch of the mesh conductor line of 207 μm.

The point to be considered in the touch panel employing the mesh conductor line is transmissivity of the touch panel and resistance of the electrode terminal in addition to the visibility of the mesh conductor line and the moiré visibility. The transmissivity of the touch panel and the resistance of the electrode terminal are closely related to a line width and a pitch of the mesh conductor line.

As the pitch of the mesh conductor line in the touch panel is smaller (a density is higher), the entire transmissivity of the touch panel becomes worse (lower), while the resistance of the electrode terminal becomes better (the resistance of the electrode terminal becomes lower). Therefore, at the time of designing the touch panel, the optimal line width and pitch of the mesh conductor line need to be determined by considering the transmissivity of the touch panel and the resistance of the electrode terminal together in addition to the visibility of the mesh conductor line and the moiré visibility.

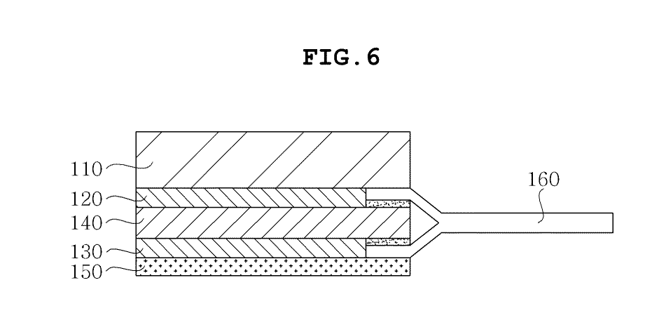

FIG. 6 is a cross-sectional view of a touch panel employing mesh conductor lines panel according to one preferred embodiment of the present invention. Although not shown in FIG. 6, both sides of a transparent substrate 140 are provided with a sensing electrode and a driving electrode, respectively. In the case of the touch panel of FIG. 6, a thickness of the electrode may be less than several μm, a thickness of a cover 110 (window glass) may be about 500 μm through 700 μm, and thicknesses of first and second adhesive layers 120 and 130 (OCA, Optical Cleared Adhesive) may be about 50 μm. In addition, a thickness of the transparent substrate 140 (PET film) may be about 100 μm and a thickness of an anti-reflection (AR) film 150 may be about 50 μm. However, limitation to materials such as the window glass, OCA, PET film, and the like and limitation to a numerical value of the thickness of each component are illustrative and do not limit a scope of the present invention. Meanwhile, FPCB assembly 160 may be mounted with a touch driving integrated circuit IC for driving the touch panel, receiving and processing touch input from the touch panel, and then outputting a touch coordinate, a touch intensity value, and the line to a host.

Among techniques of forming the electrode on both sides of the transparent substrate 140, recently, a silver halide photography technique has been actively developed. The reason that the silver halide photography technique has the limelight is that it may decrease sheet resistance of the electrode compared to the existing ITO, may mass-produce through a roll to roll process using a PET film substrate to increase price competitiveness of the touch panel, and has more excellent bending characteristics than the ITO when using a metal electrode such as silver halide, such that it is advantageously applied to a flexible display to be released to a market in the future.

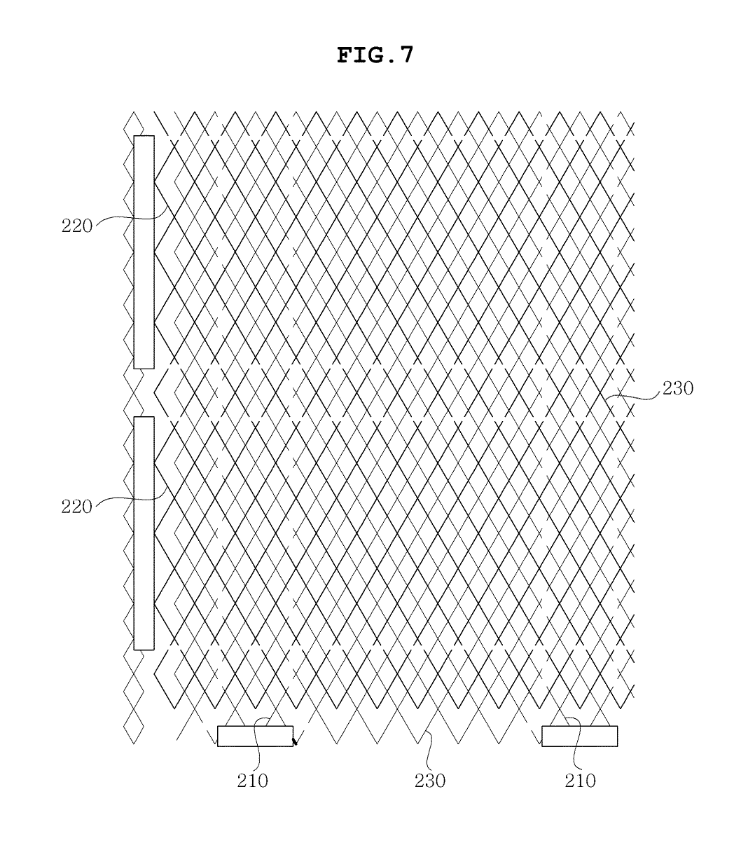

The silver halide photography technique forms the electrode (Ag metal) on the transparent substrate 140 (PET film) using an exposure process and a development process similar to a technique used in a traditional analog film photography technique. In order to form the electrode having a mesh shape, a mask needs to be pre-manufactured. The pre-manufactured mask is fixed on the transparent substrate 140 (PET film) and the mesh conductor lines are then formed on the transparent substrate (PET film) through both sides exposure process and development process. FIG. 7 is a plan view showing two sensing electrodes and two driving electrodes at a left lower end portion of the touch panel. The mesh conductor lines formed through the silver halide photography technique are as shown in FIG. 7. In the case of a sensing electrode 210 formed on one side of the transparent substrate (PET film), a width is about 1.2 mm, which is relatively narrow, and an electrode interval is 3.5 mm, which is wide. On the other hand, in the case of a driving electrode 220 formed on the other side of the transparent substrate (PET film), a width is about 4 mm, which is relatively wide, and an electrode interval is about 0.5 mm, which is narrow. The LCD display having 3.8 inches wide VGA (WVGA) resolution has a horizontal width of about 50 mm and a vertical height of about 84 mm. Therefore, in the case in which the electrode width and interval as mentioned above are applied to the LCD display having 3.8 inches wide VGA (WVGA) resolution, there may be 11 sensing electrodes 210 in the horizontal width direction and 18 driving electrodes 220 in the vertical height direction. However, the electrode width and interval, the kind of display, and the like are only examples, and a scope of the present invention is not limited thereto. Meanwhile, as shown in FIG. 7, dummy mesh conductor lines 230 are inserted between the electrodes, thereby making it possible to improve the visibility of the mesh conductor lines.

The touch panel shown in FIG. 6 has the sensing electrode 210 and the driving electrode 220 present on surfaces different from each other. However, as shown in FIG. 7 which is a plan view, in view of the visibility, it may be assumed as if the sensing electrode 210 and the driving electrode 220 are present on the same surface. In this case, the mesh conductor lines for the sensing electrode and the mesh conductor lines for the driving electrode are arranged to be misaligned to each other by a half period. This configuration is to improve the visibility of the mesh conductor line. In a touch panel according to another preferred embodiment of the present invention, the sensing electrode 210 and the driving electrode 220 may be actually present on the same surface.

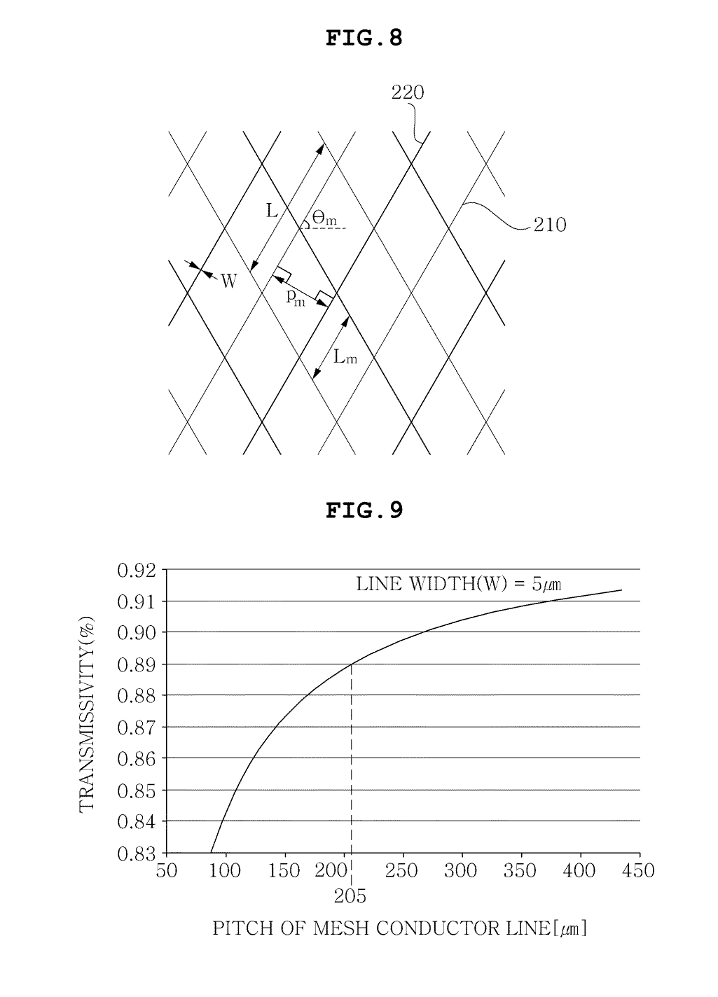

FIG. 8 is an enlarged view of enlarging the sensing electrode and the driving electrode shown in FIG. 7. As shown in FIG. 8, when defining the line width of the mesh conductor line as W, a length of a unit electrode pattern as L, a tilt angle of the pattern as θₘ, a length of a unit mesh conductor line as Lₘ, and a pitch of the unit mesh conductor line as pₘ, the following equation 1 is established.

pₘ=Lₘ×sin(2θₘ),Lₘ=L/2 (Equation 1)

For reference, the length L of the unit electrode pattern is a length of one side of a polygon formed while the mesh conductor lines of the sensing electrode 210 intersect or a polygon formed while the mesh conductor lines of the driving electrode 220 intersect, and the length Lₘ of the unit mesh conductor line is a length of a polygon formed while the mesh conductor line of the sensing electrode 210 and the mesh conductor line of the driving electrode 220 intersect each other. In addition, the pitch of the unit mesh conductor line is a length vertically connecting the mesh conductor line of an adjacent sensing electrode 210 to the mesh conductor line of the driving electrode 220.

Transmissivity Tₘ of the touch panel employing the mesh conductor line establishes the following equation 2 from transmissivity T without the mesh conductor line, the line width W of the mesh conductor line, and the pitch pₘ of the unit mesh conductor line.

Tₘ=T×(1−W/pₘ)² (Equation 2)

It may be confirmed from the equation 2 that the transmissivity Tₘ is proportional to the transmissivity T without the mesh conductor line and is inversely proportional to the line width W of the mesh conductor line.

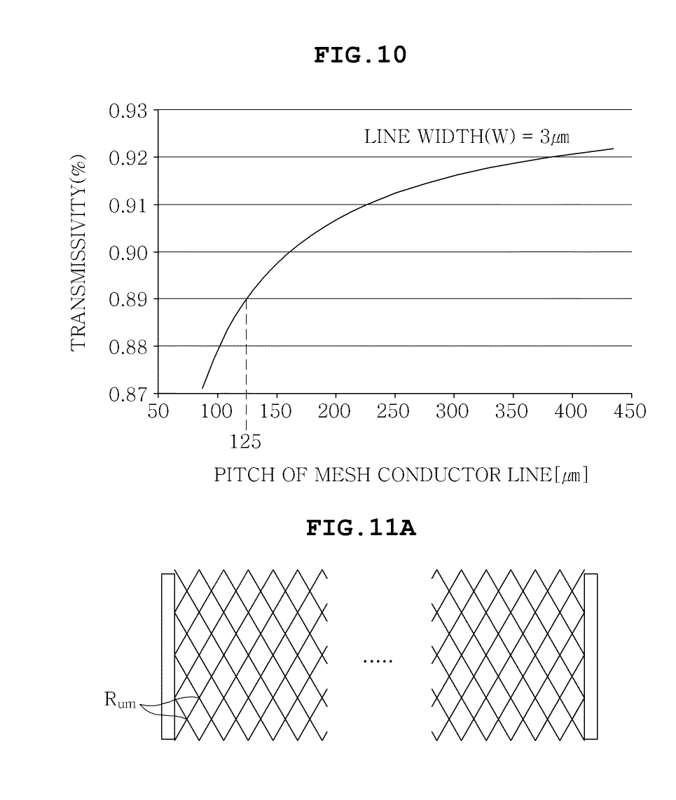

FIGS. 9 and 10 are graphs showing transmissivity of the touch panel employing the mesh conductor lines. As shown in FIG. 9, it may be confirmed that for the pitch pₘ of the mesh conductor line, as the pitch pₘ is shorter (a density of the mesh conductor line is higher), the transmissivity is decreased. The reason is that a conductor material forming the conductor line is generally an opaque metal material which does not generally transmit light. In FIG. 9, it was assumed that the line width of the mesh conductor line is 5 μm, the tilt angle θₘ of the mesh conductor line is 30° (it was known that the tilt angle θₘ of the mesh conductor line is relatively advantageous in improving the moiré in the vicinity of 30° (or 60°) relatively compared to other angles), and the transmissivity when the mesh conductor line is not present in the touch panel shown in FIG. 6 is about 93.4%.

Generally, the transmissivity required from the touch panel is 89% or more. It may be confirmed from FIG. 9 that in order to implement the transmissivity of 89%, when the line width W of the mesh conductor line is 5 μm, the pitch of the mesh conductor line is approximately 205 μm or more. In the case in which the line width W of the mesh conductor line may be decreased to 3 μm, it may be confirmed from FIG. 10 that the transmissivity of approximately 89% may be implemented at the pitch of the mesh conductor line of 125 μm. That is, when the line width of the mesh conductor line is decreased by order of 40% from 5 μm to 3 μm, the pitch may be decreased by order of 40% from 205 μm to 125 μm. However, as confirmed from FIG. 5, it may be appreciated that as the frequency fₘ of the mesh conductor line is closer to the pixel frequency f_{d} of the display, the moiré visibility becomes worse. In the case in which the pitch of the mesh conductor line is 205 μm, the moiré visibility becomes close to a local minimum in the vicinity of 207 μm which is the pitch corresponding to the half of the pixel frequency f_{d} of the display. On the other hand, in the case in which the pitch pₘ of the mesh conductor line is 125 μm, the visibility of the mesh conductor line is excellent, but the frequency fₘ of the mesh conductor line is close to the pixel frequency fₘ of the display, such that the moiré visibility becomes worse. Therefore, it may be confirmed that the line width W of the mesh conductor line of 5 μm and the pitch pₘ of the mesh conductor line of 205 an are more advantageous than the line width W of the mesh conductor line of 3 μm and the pitch pₘ of the mesh conductor line of 125 μm.

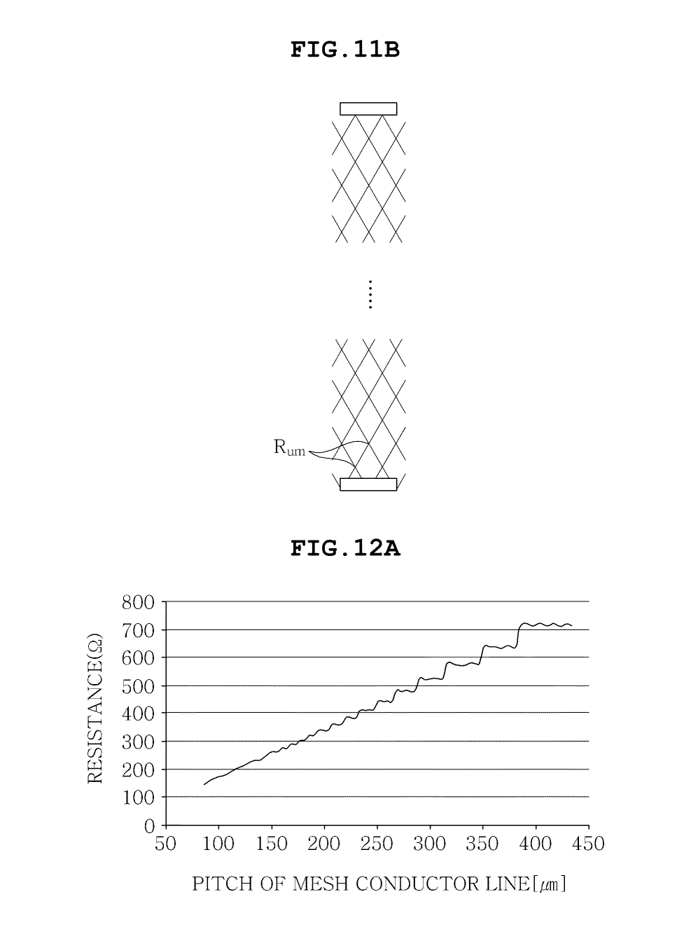

The terminal resistance of the electrode in the touch panel employing the mesh conductor line is closely related to the line width and the pitch of the mesh conductor line. FIG. 11A is a plan view showing the driving electrode of the touch panel and FIG. 11B is a plan view showing the sensing electrode of the touch panel. As shown in FIGS. 11A and 11B, Rᵤₘ represents unit resistance of a unit electrode pattern. Here, the unit resistance of the unit electrode pattern is resistance of one side of a polygon formed while the mesh conductor lines intersect. The unit resistance of the unit electrode pattern establishes the following equation 3 when conductivity of the conductor forming the mesh conductor line is σ.

Rᵤₘ=L/(σ×A),A=t×W (Equation 3)

Here, L represents the length of the unit electrode pattern as shown in FIG. 8, W represents the line width of the mesh conductor line, and t represents the thickness of the mesh conductor line.

A total of terminal resistance of the electrode is represented as the following equation 4 with respect to the driving electrode and the sensing electrode.

Rₜₒₜₐₗ_{_{—}}_{drv}=(Rᵤₘ/Nᵥ)×Nₕ,Rₜₒₜₐₗ_{_{—}}ₛₑₙ=(Rᵤₘ/Nₕ)×Nᵥ (Equation 4)

Here, in the case of the terminal resistance Rₜₒₜₐₗ_{_{—}}_{drv} of the driving electrode, Nᵥ represents the number of the unit electrode patterns in a vertical direction within an electrode width and Nₕ represents the number of the unit electrode patterns in a horizontal direction within an electrode length. In the case of the terminal resistance Rₜₒₜₐₗ_{_{—}}ₛₑₙ of the sensing electrode, Nₕ represents the number of the unit electrode patterns in the horizontal direction within the electrode width and Nᵥ represents the number of the unit electrode patterns in the vertical direction within the electrode length. In a width direction of the electrode, a parallel connection of the resistances is assumed and in a length direction of the electrode, a serial connection of the resistances is assumed.

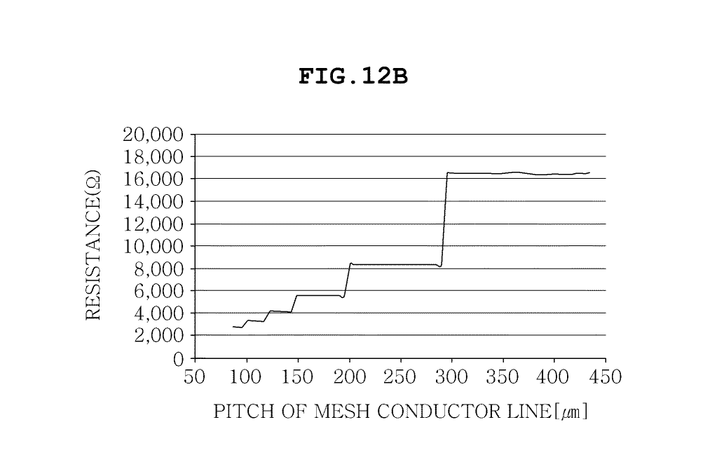

FIG. 12A is a graph showing change of a terminal resistance of the driving electrode with respect to the pitch of the mesh conductor lines and FIG. 12B is a graph showing change of a terminal resistance of the sensing electrode with respect to the pitch of the mesh conductor lines. In FIGS. 12A and 12B, it was assumed that the line width W of the mesh conductor line is 5 μm, the thickness t of the mesh conductor line is 1 μm, and the tilt angle θₘ is 30°, respectively. In addition the conductivity of the silver halide material was assumed as 2×10⁶ S/m. It is known that the conductivity of pure silver Ag is 62.9×10⁶ S/m. However, it is known that the conductivity in the case of the silver halide presently considered in the touch panel is decreased about 1/10 or more compared to the conductivity of the pure silver. The reason is that in the case of the silver halide, a silver grain combining silver (Ag) elements are connected so that they contact the adjacent grains to form an electrode. When the pitch of the mesh conductor line is 207 μm (two times the pixel pitch of the display), the terminal resistance of the driving electrode is calculated as approximately 360Ω and the terminal resistance of the sensing electrode is calculated as approximately 8.82 kΩ. As such, in order to make the terminal resistance of the sensing electrode 10 kΩ or less (at the pitch of the mesh conductor line of 260 μm or less), it is preferable to have the unit resistance Rᵤₘ of the unit electrode pattern of 50Ω or less.

It may be confirmed from FIGS. 12A and 12B that as the pitch of the mesh conductor line is shorter (the density is higher), the terminal resistance is decreased. However, once the density becomes higher, the transmissivity is decreased (see FIGS. 9 and 10) and in the case in which the pitch of the mesh conductor line is decreased near the pixel pitch of the display, moiré visibility characteristics also become worse (see FIGS. 4 and 5). Therefore, an optimal pitch of the mesh conductor line needs to be selected in the vicinity of a pitch (pₘ=2×p_{d}) minimizing the moiré visibility.

Once the pitch of the mesh conductor line minimizing the moiré phenomenon is determined, it may need to decrease the line width of the mesh conductor line in order to increase the transmissivity and improve the visibility of the mesh conductor line. However, in the case in which the line width of the mesh conductor line is decreased, the transmissivity becomes better (higher) as shown in equation 2 while the terminal resistance becomes worse (higher) as shown in equation 3. Therefore, in order to maintain the same terminal resistance even at the lower line width, it is necessarily required to increase the density of the silver grain forming the electrode. In addition, until now, there is a predetermined limitation in the minimum line width achievable using an exposure and development device in the silver halide photography technique. Presently, the implementable line width of the mesh conductor line is about 1 μm through 5 μm.

Meanwhile, while the present invention has proposed the method deriving the optimal mesh conductor lines in the touch panel using the silver halide photography technique, this is merely an example and the scope of the present invention is not limited to the silver halide photography technique. For example, a theory of the present invention may be equally applied to even the case in which the optimal mesh conductor lines are derived in the touch panel using a copper (Cu) plating method or a metal sputtering method.

According to the preferred embodiment of the present invention, in the case in which the pixel arrangement structure of the display is given, the design parameters of the mesh conductor lines optimized in view of visibility, moiré visibility, transmissivity, and terminal resistance of the mesh conductor lines may be easily derived. Therefore, when the touch panel employing the mesh conductor lines is manufactured, trial and error may be decreased, the development period may be shortened, and the efficiency of the development may be improved. For example, assuming that the mesh conductor lines in which the sample manufacture needs to be attempted have line widths of five kinds, pitches of ten kinds, and thickness of two kinds, after attempting the sample manufacture of a total of 100 times, it is possible to find optimal conditions. On the other hand, once the pitch of the mesh conductor lines is determined to a specific value using the design technique proposed from the present invention, the times of attempting the sample manufacture may be significantly decreased to 10.

In addition, according to the preferred embodiment of the present invention, quality satisfaction of the customer may be increased and the touch panel employing the mesh conductor lines may be increasingly used in the future by providing the optimal touch panel in which the visibility and the moiré visibility of the mesh conductor lines blocking the mass-production of the touch panel employing the mesh conductor lines are minimized.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel, comprising:
mesh conductor lines,
wherein a pitch of the mesh conductor line has a value selected from pₘ=2×p_{d}(fₘ=f_{d}/2, pₘ≦260 μm),
wherein pₘ is a pitch of the mesh conductor line, p_{d} is a pixel pitch of a display, fₘ is a frequency 1/pₘ of the mesh conductor line, and f_{d} is a pixel frequency 1/p_{d} of the display.

2. The touch panel as set forth in claim 1, wherein the mesh conductor lines have a line width of 1 μm through 5 μm.

3. The touch panel as set forth in claim 1, wherein the mesh conductor lines have a tilt angle of 30° or 60°.

4. The touch panel as set forth in claim 1, further comprising sensing electrodes and driving electrodes configured of the mesh conductor lines.

5. The touch panel as set forth in claim 4, wherein the sensing electrodes and the driving electrodes are formed on surfaces different from each other, and the mesh conductor lines of the sensing electrode and the mesh conductor lines of the driving electrode are arranged to be misaligned to each other by a half period.

6. The touch panel as set forth in claim 4, wherein the sensing electrodes and the driving electrodes are formed on the same surface as each other.

7. A touch panel, comprising:
sensing electrodes and driving electrodes configured of the mesh conductor lines,
wherein when a length of one side of a polygon formed by intersecting the mesh conductor lines of the sensing electrode or a polygon formed by intersecting the mesh conductor lines of the driving electrode is defined as a length of a unit electrode pattern,
a length of one side of a polygon formed by intersecting the mesh conductor line of the sensing electrode and the mesh conductor line of the driving electrode with each other is defined as a length of a unit mesh conductor line, and
a length vertically connecting between the mesh conductor line of the sensing electrode and the mesh conductor line of the driving electrode adjacent to each other is defined as a pitch of the unit mesh conductor line,
the length of the unit electrode pattern has a value selected from L=2×Lₘ=2×pₘ/sin(2θₘ),
wherein L is the length of the unit electrode pattern, Lₘ is the length of the unit mesh conductor line, pₘ is the pitch of the unit mesh conductor line, and θₘ is a tilt angle of the mesh conductor line.

8. A touch panel, comprising:
mesh conductor lines,
wherein a line width of the mesh conductor line and a pitch of the mesh conductor line have values selected from Tₘ=T×(1−W/pₘ)²≧89%, 1 μm≦W≦5 μm, pₘ≦260 μm so that the touch panel satisfies transmissivity of 89% or more,
wherein Tₘ is transmissivity of the touch panel, T is transmissivity of the touch panel without the mesh conductor line, W is the line width of the mesh conductor line, and pₘ is the pitch of the mesh conductor line.

9. The touch panel as set forth in claim 8, wherein the mesh conductor lines have a tilt angle of 30° or 60°.

10. The touch panel as set forth in claim 8, further comprising sensing electrodes and driving electrodes configured of the mesh conductor lines.

11. The touch panel as set forth in claim 10, wherein the sensing electrodes and the driving electrodes are formed on surfaces different from each other, and the mesh conductor lines of the sensing electrode and the mesh conductor lines of the driving electrode are arranged to be misaligned to each other by a half period.

12. The touch panel as set forth in claim 10, wherein the sensing electrodes and the driving electrodes are formed on the same surface as each other.

13. A touch panel, comprising:
mesh conductor lines,
wherein when a resistance of one side of a polygon formed by intersecting the mesh conductor lines is defined as a unit resistance of a unit electrode pattern, and
a length of one side of a polygon formed by intersecting the mesh conductor lines is defined as a length of a unit electrode pattern,
conductivity of a conductor forming the mesh conductor lines, a thickness of the mesh conductor line, and a line width of the mesh conductor line have values selected from Rᵤₘ=L/(σ×A), A=t×W so that the unit electrode pattern has the unit resistance of 50Ω or less,
wherein Rᵤₘ is the unit resistance of the unit electrode pattern, L is the length of the unit electrode pattern, σ is the conductivity of the conductor forming the mesh conductor lines, t is the thickness of the mesh conductor line, and W is the line width of the mesh conductor line.

14. The touch panel as set forth in claim 13, wherein the mesh conductor lines have a tilt angle of 30° or 60°.

15. The touch panel as set forth in claim 13, further comprising sensing electrodes and driving electrodes configured of the mesh conductor lines.

16. The touch panel as set forth in claim 15, wherein the sensing electrodes and the driving electrodes are formed on surfaces different from each other, and the mesh conductor line of the sensing electrode and the mesh conductor lines of the driving electrode are arranged to be misaligned to each other by a half period.

17. The touch panel as set forth in claim 15, wherein the sensing electrodes and the driving electrodes are formed on the same surface as each other.
